(19) United States
(12) Patent Application Publication
(10) Pub. No.: US 2012/0314390 A1
(43) Pub. Date: Dec. 13, 2012

(54) MULTILAYER CIRCUIT BOARD

(75) Inventor: Jung-Chien Chang, Xinzhuang City (TW)

(73) Assignee: MUTUAL-TEK INDUSTRIES CO., LTD., Xinzhuang City (TW)

(21) Appl. No.: 13/593,361

(22) Filed: Aug. 23, 2012

Related U.S. Application Data
(63) Continuation-in-part of application No. 13/034,404, filed on Feb. 24, 2011.

(30) Foreign Application Priority Data
Mar. 3, 2010 (TW) 99106167
Aug. 29, 2011 (TW) 100216097

(51) Int. Cl. H05K 1/18

(52) U.S. Cl. 361/761

(57) ABSTRACT

A multilayer circuit board includes a first circuit layer, an insulating layer, a second circuit layer, an intermediate frame, an electronic element, and a third circuit layer. The insulating layer is disposed on the first circuit layer, and the second circuit layer is disposed on the insulating layer. The intermediate frame is disposed on the second circuit layer and has an accommodating space. The electronic element is disposed on the second circuit layer, electrically connected to the second circuit layer and located in the accommodating space. The third circuit layer is disposed on the intermediate frame.

### CROSS REFERENCE TO RELATED APPLICATIONS

This application claims the right of priority based on Taiwan Patent Application No. 100216097, entitled “MULTILAYER CIRCUIT BOARD,” filed on Aug. 29, 2011, which is incorporated herein by reference and assigned to the assignee herein. In addition, this application is a continuation-in-part of U.S. application Ser. No. 13/034,404, entitled “COMBINED MULTILAYER CIRCUIT BOARD HAVING EMBEDDED COMPONENTS AND MANUFACTURING METHOD OF THE SAME,” filed on Feb. 24, 2011, which claims the right of priority based on Taiwan Patent Application No. 99106167, entitled “COMBINED MULTILAYER CIRCUIT BOARD HAVING EMBEDDED COMPONENTS AND MANUFACTURING METHOD OF THE SAME,” filed on Mar. 3, 2010.

### FIELD OF THE INVENTION

The present invention relates to a circuit board, and more particularly, to a multilayer circuit board.

### BACKGROUND OF THE INVENTION

A technique involving integrating various electronic parts and components into a printed circuit board has been noticed and developed in recent years. The development of advanced semiconductor technology often brings about a variety of functionally complex and compact electronic products. According to the trend, the demand for the multi-function of a circuit board expands, and more electronic parts and components to be integrated into a circuit board are required. To meet the demand and the requirement, it is necessary to improve the structure of a multilayer circuit board and manufacturing method thereof persistently.

### SUMMARY OF THE INVENTION

The present invention provides a multilayer circuit board.

The present invention provides a multilayer circuit board that comprises a first circuit layer, an insulating layer, a second circuit layer, an intermediate frame, an electronic element, and a third circuit layer. The insulating layer is disposed on the first circuit layer. The second circuit layer is disposed on the insulating layer. The intermediate frame is disposed on the second circuit layer and has an accommodating space. The electronic element is disposed on the second circuit layer, electrically connected to the second circuit layer, and located in the accommodating space. The third circuit layer is disposed on the intermediate frame.

In an embodiment of the present invention, the multilayer circuit board further comprises at least one conductive via penetrating the insulating layer and electrically connecting the first circuit layer and the second circuit layer.

In an embodiment of the present invention, the multilayer circuit board further comprises at least one conductive through hole penetrating the insulating layer, the second circuit layer, and the intermediate frame and electrically connecting the first circuit layer, the second circuit layer, and the third circuit layer.

In an embodiment of the present invention, the conductive through hole is disposed on a side surface of the multilayer circuit board.

In an embodiment of the present invention, at least one of the first circuit layer and the third circuit layer has a pad, and the pad is disposed at an end of the conductive through hole.

In an embodiment of the present invention, the multilayer circuit board further comprises a vent hole. The accommodating space communicates with an external environment via the vent hole.

In an embodiment of the present invention, an inner diameter of the vent hole ranges between 0.05 mm and 0.2 mm.

In an embodiment of the present invention, the vent hole penetrates the third circuit layer to communicate with the accommodating space.

In an embodiment of the present invention, the multilayer circuit board further comprises an adhesive layer. The third circuit layer is disposed on the intermediate frame through the adhesive layer. The vent hole penetrates at least one of the third circuit layer and the adhesive layer to communicate with the accommodating space.

In an embodiment of the present invention, the multilayer circuit board further comprises a filler. The filler and the electronic element occupy the accommodating space completely.

In an embodiment of the present invention, the multilayer circuit board further comprises an adhesive layer. The third circuit layer is disposed on the intermediate frame through the adhesive layer.

In an embodiment of the present invention, the multilayer circuit board further comprises an adhesive layer. The intermediate frame is disposed on the second circuit layer through the adhesive layer.

In an embodiment of the present invention, the multilayer circuit board further comprises a support layer. The support layer is disposed between the intermediate frame and the third circuit layer.

In an embodiment of the present invention, the intermediate frame is a dielectric frame.

In an embodiment of the present invention, the intermediate frame is a multilayer frame and at least comprises a fourth circuit layer and a dielectric layer.

The aforesaid features and advantages of the present invention are further illustrated with the following description and the appended claims or the embodiments described hereunder.

### BRIEF DESCRIPTION OF THE DRAWINGS

FIG. 1A is a schematic top view of a multilayer circuit board according to a first embodiment of the present invention.

FIG. 1B is a schematic cross-sectional view of the multilayer circuit board taken along line A-A of FIG. 1A.

FIG. 2A to FIG. 2K are schematic views showing a method of manufacturing the multilayer circuit board according to the first embodiment of the present invention.

FIG. 3 is a schematic cross-sectional view of a multilayer circuit board according to a second embodiment of the present invention.

FIG. 4 is a schematic top view of a multilayer circuit board according to a third embodiment of the present invention.

### DETAILED DESCRIPTION OF THE INVENTION

The preferred embodiments of the present invention will now be described in greater details by referring to the drawings that accompany the present application. It should be noted that the features illustrated in the drawings are not necessarily drawn to scale. Descriptions of well-known components, materials, and process techniques are omitted so as to not unnecessarily obscure the embodiments of the invention. Any devices, components, materials, and steps described in the embodiments are only for illustration and not intended to limit the scope of the present invention.

### First Embodiment

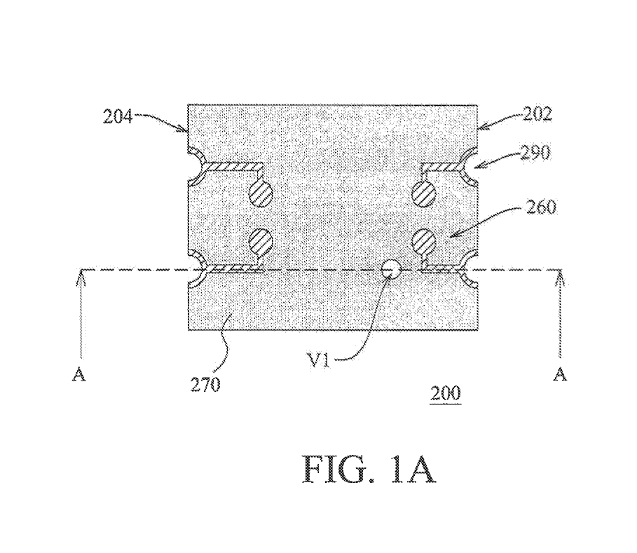

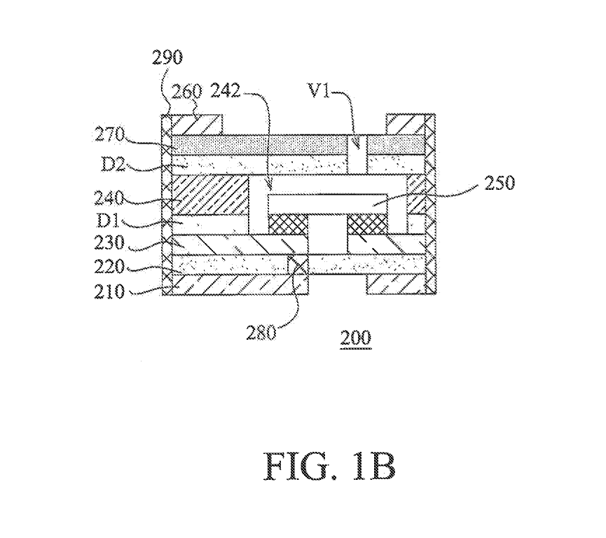

FIG. 1A is a schematic top view of a multilayer circuit board according to a first embodiment of the present invention. FIG. 1B is a schematic cross-sectional view of the multilayer circuit board taken along line A-A of FIG. 1A. Referring to FIG. 1A and FIG. 1B, in the first embodiment, a multilayer circuit board 200 comprises three circuit layers 210, 230, 260, an insulating layer 220, an intermediate frame 240, and an electronic element 250. The insulating layer 220 is disposed between the circuit layer 210 and the circuit layer 230. The circuit layers 210, 230, 260 may be made of copper. The insulating layer 220 may be a prepreg comprising fiberglasses or a glue layer comprising glue material only.

The intermediate frame 240 is disposed on the circuit layer 230 and has an accommodating space 242. In this embodiment, for example, the intermediate frame 240 is a dielectric frame. The intermediate frame 240 is disposed on the circuit layer 230 through an adhesive layer D1. The adhesive layer D1 is a prepreg, for example. In another embodiment, the intermediate frame is a multilayer frame which at least comprises another circuit layer and a dielectric layer but is not shown in the drawings.

The electronic element 250 is disposed on the circuit layer 230, electrically connected to the circuit layer 230, and located in the accommodating space 242. The electronic element 250 may be selected from a magnetic element, a quartz chip, a vibrational chip, a MEMS chip, or any other appropriate electronic part, including a mechanical electronic part. The electronic element 250 may be disposed on the circuit layer 230 by means of surface mount technology (SMT). In another embodiment, the electronic element 250 may be disposed on the circuit layer 230 by any other means, such as wire bonding technology that is not shown in the drawings.

The circuit layer 260 is disposed on the intermediate frame 240. In this embodiment, the circuit layer 260 is disposed on a support layer 270, and the support layer 270 is disposed on the intermediate frame 240 through another adhesive layer D2. For example, the adhesive layer D2 is a prepreg, and the support layer 270 is made of curing resin. The accommodating space 242 of the intermediate frame 240 is not occupied completely, and thus the support layer 270 can provide the required structural strength such that the external surface of the circuit layer 260 above the accommodating space 242 is substantially flat.

The multilayer circuit board 200 further comprises at least one conductive via 280 (one conductive via 280 is depicted schematically in FIG. 1B), at least one conductive through hole 290 (four conductive through holes 290 are depicted schematically in FIG. 1A), and a vent hole V1. The conductive via 280 penetrates the insulating layer 220 and electrically connects the circuit layers 210, 230. In another embodiment, the conductive via 280 is dispensable.

Each of the conductive through holes 290 penetrates the insulating layer 220, the circuit layer 230, the adhesive layer D1, the intermediate frame 240, the adhesive layer D2, and the support layer 270, and electrically connects the circuit layer 210, the circuit layer 230, and the circuit layer 260. In this embodiment, two of the conductive through holes 290 are disposed on a side surface 202 of the multilayer circuit board 200, and the other two of the conductive through holes 290 are disposed on another side surface 204 of the multilayer circuit board 200, wherein the side surface 202 is opposite to the side surface 204. In another embodiment, the conductive through holes 290 are dispensable.

The vent hole V1 penetrates the adhesive layer D2 and the support layer 270 and communicates with the accommodating space 242 such that the accommodating space 242 communicates with an external environment through the vent hole V1. In this embodiment, an inner diameter of the vent hole V1 ranges between 0.05 mm and 0.2 mm. The vent hole V1 enables the accommodating space 242 and the external environment almost has the same air pressure. It should be noted that the vent hole V1 can penetrate any circuit of the circuit layer 260 (i.e. the vent hole V1 can penetrate the circuit layer 260) if the circuit passes through the preset position of the vent hole V1, but the above-mentioned situation is not shown in the drawings. In another embodiment, if the internal pressure of the enclosed accommodating space 242 is designed to fail within an allowable pressure range, the vent hole V1 will be dispensable.

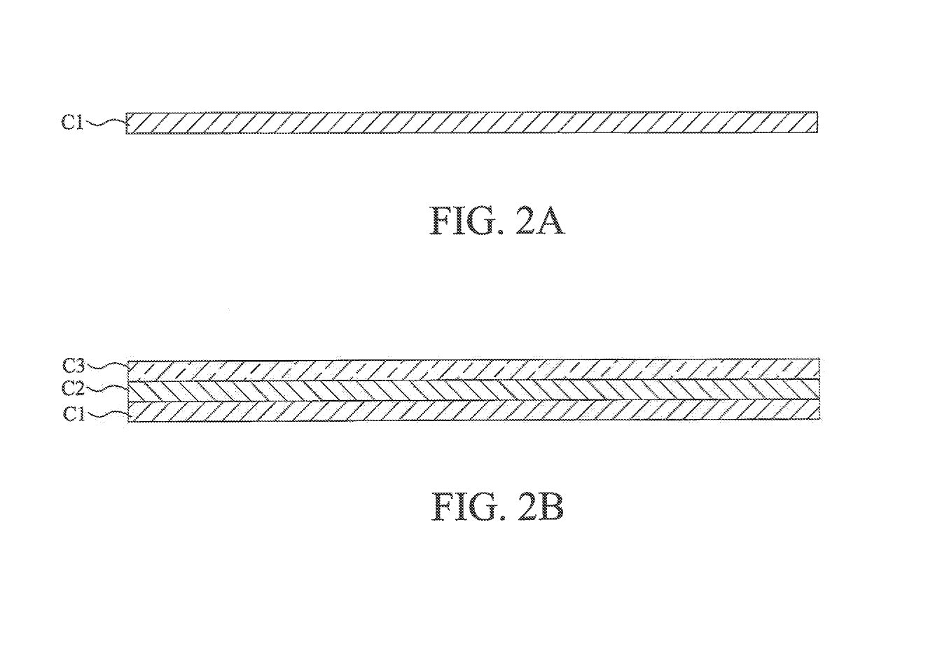

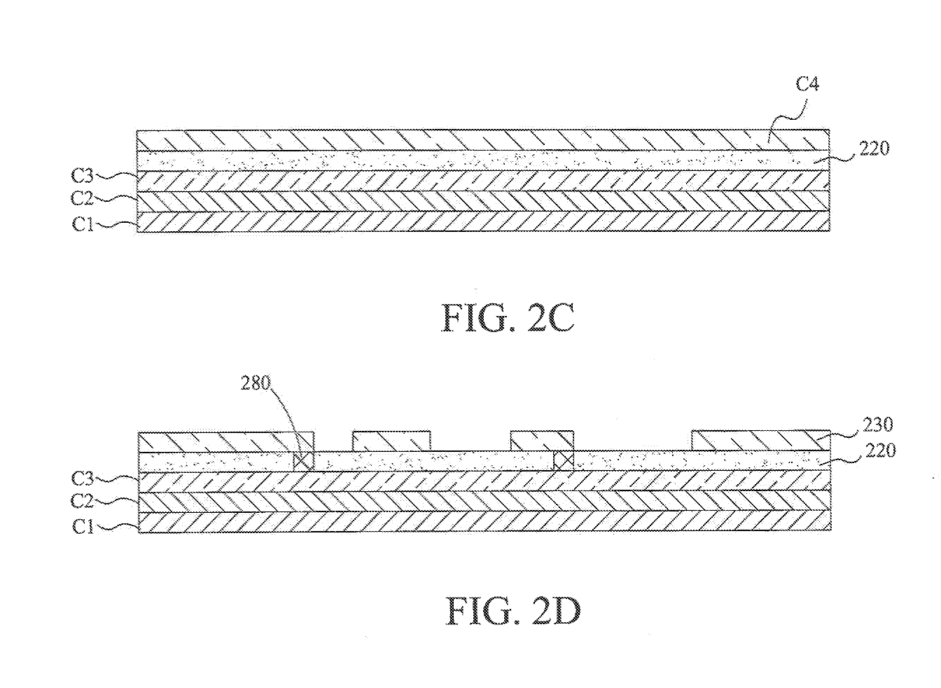

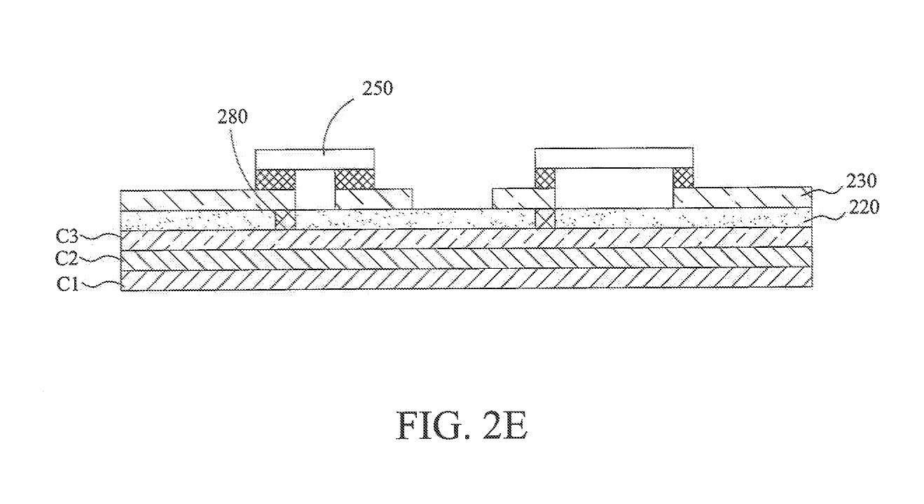

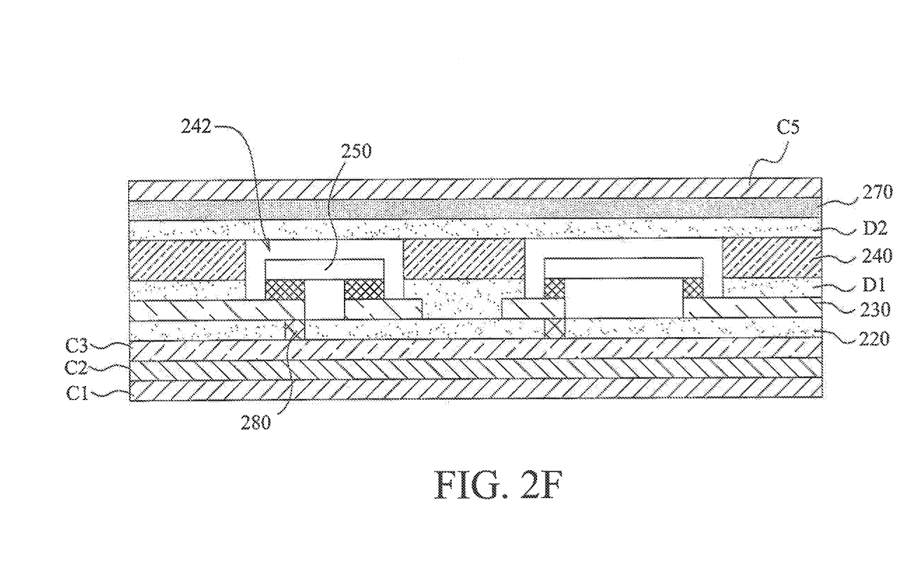

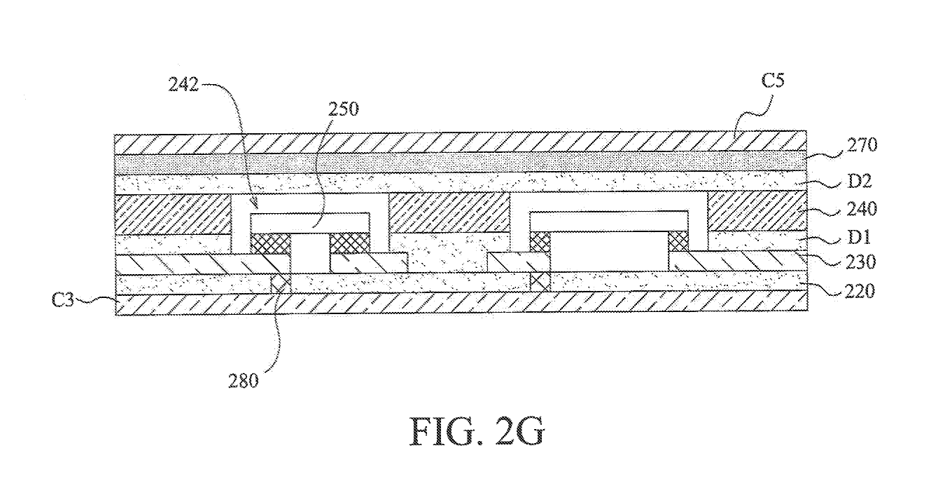

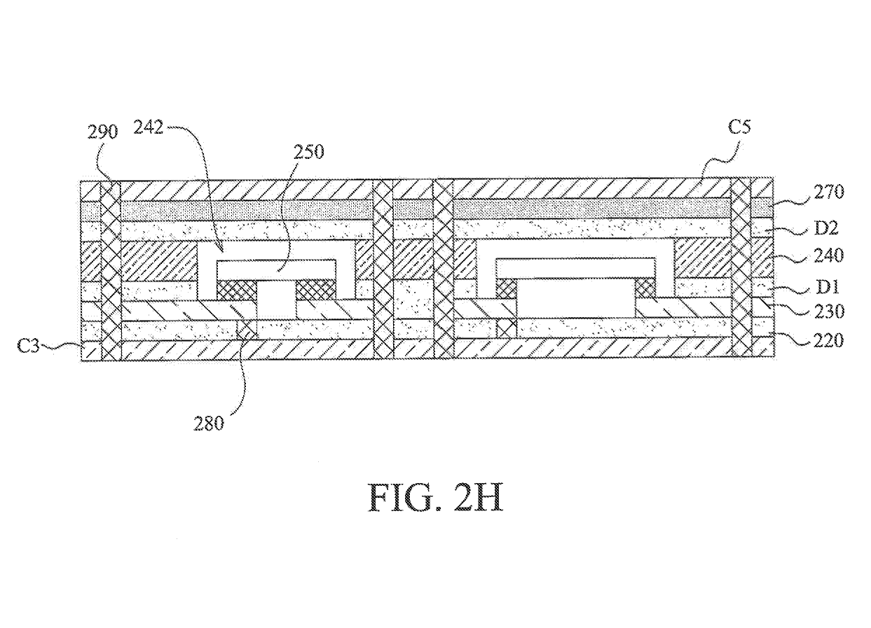

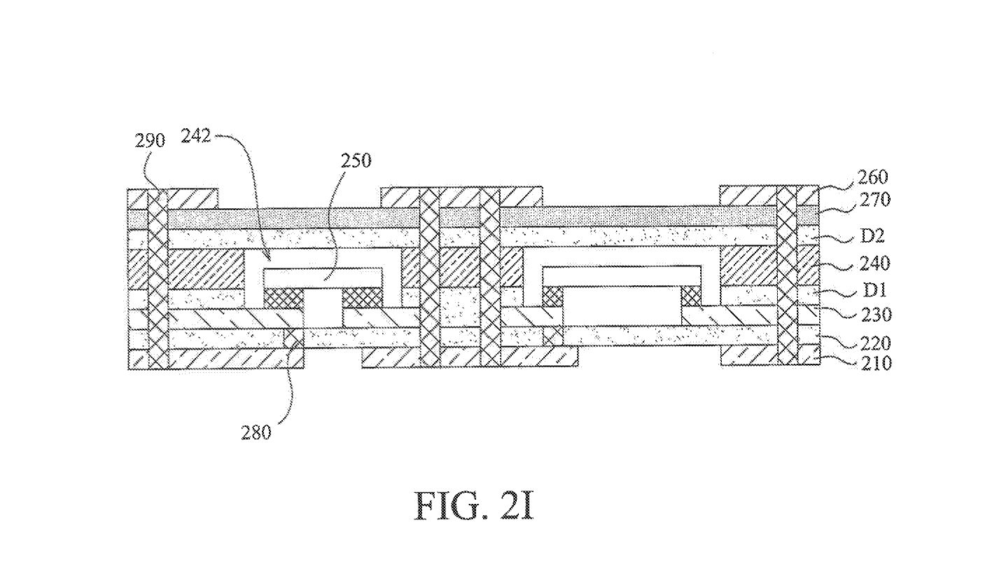

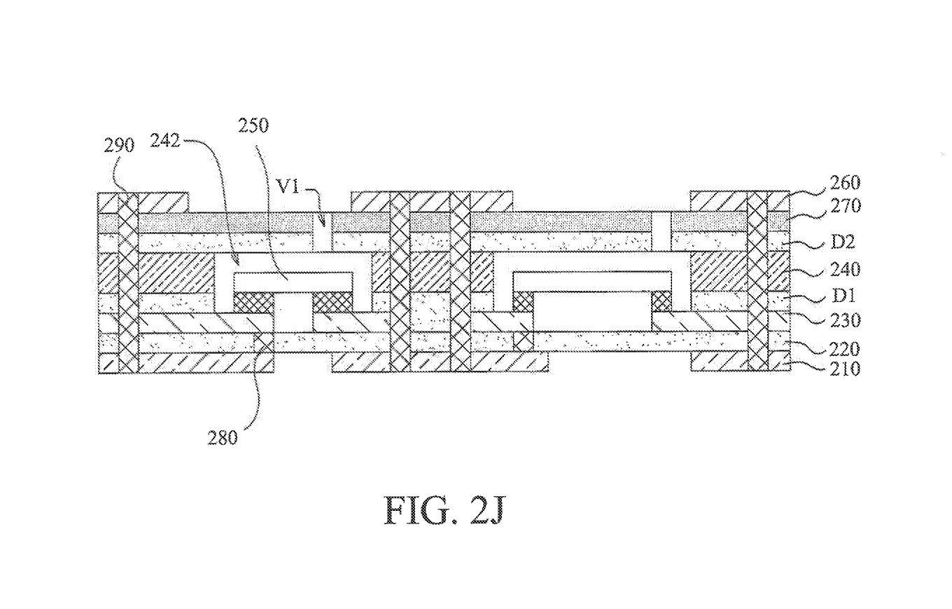

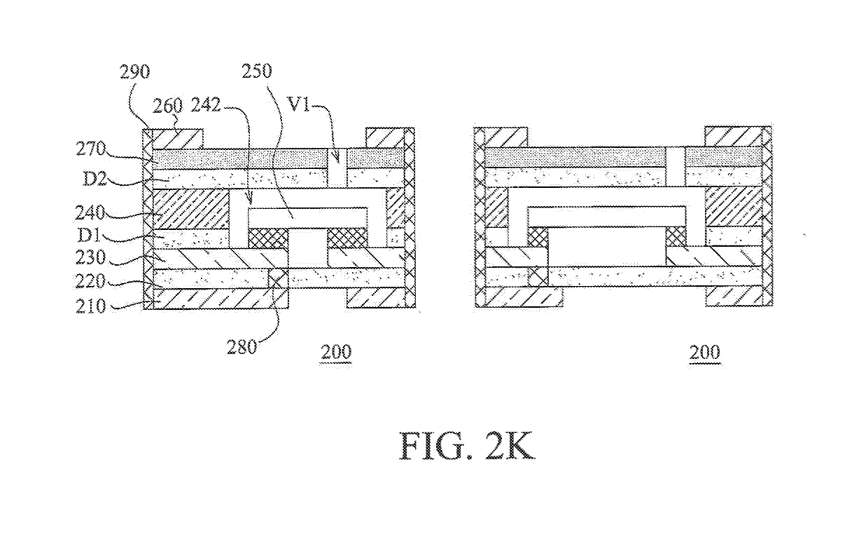

The method of manufacturing the multilayer circuit board 200 is further described hereunder. FIG. 2A to FIG. 2K are schematic views showing a method of manufacturing the multilayer circuit board according to the first embodiment of the present invention. First, referring to FIG. 2A, a conductive layer C1 such as a copper foil layer is provided. Next, referring to FIG. 2B, for example, a conductive layer C2 which may be made of nickel and a conductive layer C3 which may be made of copper are formed on the conductive layer C1 in sequence by means of electroplating. Referring to FIG. 2B, the conductive layer C2 which may be made of nickel can function as an etch-stop layer.

Next, referring to FIG. 2C, for example, a conductive layer C4 and the insulating layer 220 are formed on the conductive layer C3 by means of lamination such that the insulating layer 220 is located between the conductive layer C4 and the conductive layer C3. Prior to the laminating step of FIG. 2C, the conductive layer C4 and the insulating layer 220 may compose a pre-formed resin coated copper (RCC). That is, the insulating layer 220 is a glue layer of the resin coated copper, and the conductive layer C4 is a copper foil layer of the resin coated copper. Alternatively, prior to the laminating step of FIG. 2C, the conductive layer C4 and the insulating layer 220 may be a copper foil layer and a prepreg that are separated from each other beforehand. The above-mentioned is selectively implemented according to the manufacturer's requirement.

Next, referring to FIG. 2D, for example, multiple conductive vias 280 are formed by means of laser processing and electroplating, and the circuit layer 230 is formed from the conductive layer C4 by means of microlithography and etching such that each of the conductive vias 280 penetrates the insulating layer 220 and electrically connects the circuit layer 230 and the conductive layer C3. It should be noted that since the conductive layers C1, C2, C3 can function as a base, the conductive layers C1, C2, C3 have sufficient structural strength and do not bend such that the external surface of the circuit layer 230 still maintains its flatness to a certain extent at the processing step of FIG. 2D or any processing step thereafter, Next, referring to FIG. 2E, for example, multiple electronic elements 250 are disposed on the circuit layer 230 by means of surface mount technology (SMT).

Next, referring to FIG. 2F, for example, the adhesive layer D1, the intermediate frame 240, the adhesive layer D2, the support layer 270, and a conductive layer C5 are sequentially formed on the circuit layer 230 by means of lamination such that each of the electronic elements 250 is located in the corresponding accommodating space 242. The adhesive layers D1, D2 are non-flowing prepregs characterized in that they do not produce any significant amount of glue liquid after vacuum thermal pressing. Therefore, glue liquid is almost absent in the accommodating spaces 242 or insignificant in quantity even if it exists therein. It should he noted that prior to the laminating step of FIG. 2F, the support layer 270 and the conductive layer C5 may compose a pre-formed thin sheet. After the laminating step of FIG. 2F, since the accommodating spaces 242 of the intermediate frame 240 are not completely filled, the support layer 270 can provide the required structural strength such that the external surface of the conductive layer C5 on the accommodating spaces 242 is flat.

Next, referring to FIG. 2G, the conductive layers C1, C2 are removed. Next, referring to FIG. 2H, multiple conductive through holes 290 are formed by means of mechanical drilling and electroplating. Each of the conductive through holes 290 penetrates the insulating layer 220, the circuit layer 230, the adhesive layer D1, the intermediate frame 240, the adhesive layer D2, and the support layer 270 and electrically connects the conductive layer C5, the circuit layer 230, and the conductive layer C3. It should be noted that, in this step, other conductive vias 280 electrically connecting the circuit layer 230 and the conductive layer C3 can be further formed by means of laser processing and electroplating. In addition, the conductive vias 280 formed in the step of FIG. 2D can be alternatively formed along with the conductive through holes 290 in the step of FIG. 2H, depending on the manufacturer's requirement.

Next, referring to FIG. 2I, for example, by means of microlithography and etching, the circuit layer 260 is formed from the conductive layer C5, and the circuit layer 210 is formed from the conductive layer C3. Next, referring to FIG. 2J, multiple vent holes V1 are formed. Each of the vent holes V1 penetrates the adhesive layer D2 and the support layer 270 and communicates with the corresponding accommodating space 242 such that each of the accommodating spaces 242 communicates with an external environment through the corresponding vent hole V1. Finally, referring to FIG. 2K, multilayer circuit boards 200 are formed by means of singulating process. In this step, for example, singulating process is carried out by cutting each of the conductive through holes 290 through the center of each of the conductive through holes 290 as the baseline for cutting.

### Second Embodiment

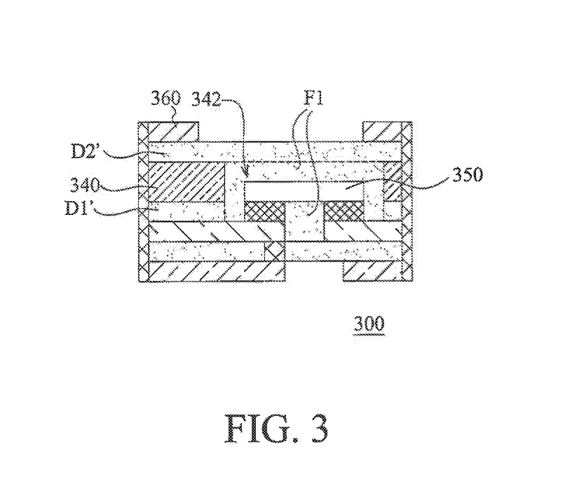

FIG. 3 is a schematic cross-sectional view of a multilayer circuit board according to a second embodiment of the present invention. Referring to FIG. 3, the difference between a multilayer circuit board 300 of this embodiment and the multilayer circuit board 200 of the first embodiment lies in that the multilayer circuit board 300 does not have any vent hole and any support layer, and a filler F1 is present in an accommodating space 342 of an intermediate frame 340.

In the second embodiment, adhesive layers D1′, D2′ are flowing prepregs, and thus during the laminating process (please referring to FIG. 2F) the adhesive layers D1′, D2′ can flow into the accommodating space 342 to form the filler F1. Hence, the filler F1 and electronic elements 350 together fill the accommodating space 342 completely.

Because the accommodating space 342 is completely filled with the filler F1 and the electronic elements 350, the intermediate frame 340 and the filler F1 together have sufficient structural strength to support a circuit layer 360. Hence, the support layer 270 (see FIG. 1B) is not necessary to be disposed between the circuit layer 360 and the adhesive layer D2′. Furthermore, since the filler F1 and the electronic elements 350 together fill the accommodating space 342 completely, the vent hole V1 (see FIG. 1B) is dispensable, too.

### Third Embodiment

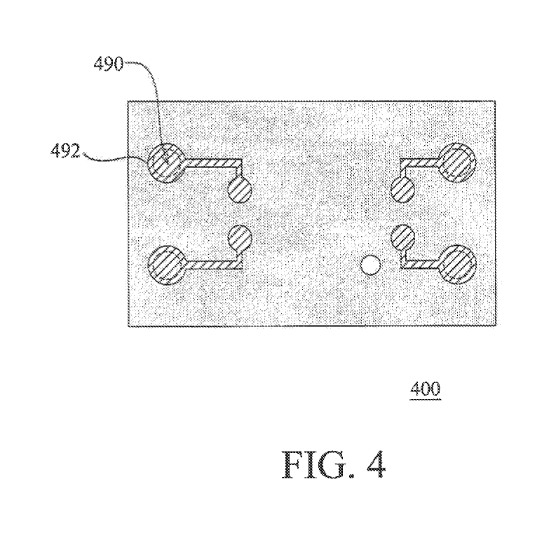

FIG. 4 is a schematic top view of a multilayer circuit board according to a third embodiment of the present invention. Referring to FIG. 4, the difference between a multilayer circuit board 400 of this embodiment and the multilayer circuit board 200 of the first embodiment lies in that the appearance of each of conductive through holes 490 of the multilayer circuit board 400 remains intact and is not cut. In other words, in singulating process, the baseline for cutting of the multilayer circuit board 200 is different from the baseline for cutting of the multilayer circuit board 400 (please refer to FIG. 2K and its related description).

Furthermore, a pad 492 is disposed at each end of each of the conductive through holes 490 of the multilayer circuit board 400.

The foregoing preferred embodiments are provided to illustrate and disclose the technical features of the present invention, and are not intended to be restrictive of the scope of the present invention. Hence, all equivalent variations or modifications made to the foregoing embodiments without departing from the spirit embodied in the disclosure of the present invention should fall within the scope of the present invention as set forth in the appended claims.

1. A multilayer circuit board comprising:
a first circuit layer;
an insulating layer disposed on the first circuit layer;
a second circuit layer disposed on the insulating layer;
an intermediate frame disposed on the second circuit layer and having an accommodating space;
an electronic element disposed on the second circuit layer, electrically connected to the second circuit layer, and located in the accommodating space; and
a third circuit layer disposed on the intermediate frame.

2. The multilayer circuit board as claimed in claim 1, further comprising at least one conductive via penetrating the insulating layer and electrically connecting the first circuit layer and the second circuit layer.

3. The multilayer circuit board as claimed in claim 1, further comprises at least one conductive through hole penetrating the insulating layer, the second circuit layer, and the intermediate frame and electrically connecting the first circuit layer, the second circuit layer, and the third circuit layer.

4. The multilayer circuit board as claimed in claim 3, wherein the conductive through hole is disposed on a side surface of the multilayer circuit board.

5. The multilayer circuit board as claimed in claim 3, wherein at least one of the first circuit layer and the third circuit layer has a pad, and the pad is disposed at an end of the conductive through hole.

6. The multilayer circuit board as claimed in claim 1, further comprising a vent hole, wherein the accommodating space communicates with an external environment via the vent hole.

7. The multilayer circuit board as claimed in claim 6, wherein an inner diameter of the vent hole ranges between 0.05 mm and 0.2 mm.

8. The multilayer circuit board as claimed in claim 6, wherein the vent hole penetrates the third circuit layer to communicate with the accommodating space.

9. The multilayer circuit board as claimed in claim 6, further comprising an adhesive layer, wherein the third circuit layer is disposed on the intermediate frame through the adhesive layer, and the vent hole penetrates at least one of the third circuit layer and the adhesive layer to communicate with the accommodating space.

10. The multilayer circuit board as claimed in claim 1, further comprising a filler, wherein the filler and the electronic element occupy the accommodating space completely.

11. The multilayer circuit board as claimed in claim 1, further comprising an adhesive layer, wherein the third circuit layer is disposed on the intermediate frame through the adhesive layer.

12. The multilayer circuit board as claimed in claim 1, further comprising an adhesive layer, wherein the intermediate frame is disposed on the second circuit layer through the adhesive layer.

13. The multilayer circuit board as claimed in claim 1, further comprising a support layer, wherein the support layer is disposed between the intermediate frame and the third circuit layer.

14. The multilayer circuit board as claimed in claim 1, wherein the intermediate frame is a dielectric frame.

15. The multilayer circuit board as claimed in claim 1, wherein the intermediate frame is a multilayer frame and at least comprises a fourth circuit layer and a dielectric layer.
